(19) United States
(12) Patent Application Publication
(10) Pub. No.: US 2025/0232975 A1
(43) Pub. Date: Jul. 17, 2025

(54) METHOD OF PROCESSING SUBSTRATE, METHOD OF MANUFACTURING SEMICONDUCTOR DEVICE, SUBSTRATE PROCESSING APPARATUS, AND RECORDING MEDIUM

(71) Applicant: KOKUSAI ELECTRIC CORPORATION, Tokyo (JP)

(72) Inventors: Kimihiko NAKATANI, Toyama-shi (JP); Nagisa SUYAMA, Toyama-shi (JP); Tomoya NAGAHASHI, Toyama-shi (JP)

(73) Assignee: KOKUSAI ELECTRIC CORPORATION, Tokyo (JP)

(21) Appl. No.: 19/058,670

(22) Filed: Feb. 20, 2025

Related U.S. Application Data
(63) Continuation of application No. PCT/JP2022/032455, filed on Aug. 29, 2022.

(51) Int. Cl. H01L 21/02; C23C 16/52

(52) U.S. Cl. CPC H01L 21/0228; C23C 16/52; H01L 21/02208

(57) ABSTRACT

A film is formed on the substrate by performing a cycle a predetermined number of times, the cycle including: (a) forming a first layer by supplying a first precursor and an addition agent to the substrate, producing a second precursor that is chemically more stable than the first precursor, and exposing and adsorbing the first precursor and the second precursor to a surface of the substrate; and (b) modifying the first layer into a second layer by supplying a reactant to the substrate.

### CROSS-REFERENCE TO RELATED APPLICATION

This application is a Bypass Continuation Application of PCT International Application No. PCT/JP2022/032455, filed on Aug. 29, 2022, the entire content of which is incorporated herein by reference.

### TECHNICAL FIELD

The present disclosure relates to a method of processing a substrate, a method of manufacturing a semiconductor device, a substrate processing apparatus, and a recording medium.

### BACKGROUND

As a process of manufacturing a semiconductor device, a process for forming a film on a substrate is sometimes performed.

With miniaturization of semiconductor devices, there is a strong demand for improvements in step coverage of a film formed on a substrate.

### SUMMARY

Embodiments of the present disclosure provide a technique capable of improving step coverage of a film formed on a substrate.

According to embodiments of the present disclosure, there is provided a technique that includes forming a film on the substrate by performing a cycle a predetermined number of times, the cycle including: (a) forming a first layer by supplying a first precursor and an addition agent to the substrate, producing a second precursor that is chemically more stable than the first precursor and exposing, and adsorbing the first precursor and the second precursor to a surface of the substrate; and (b) modifying the first layer into a second layer by supplying a reactant to the substrate.

### BRIEF DESCRIPTION OF DRAWINGS

The accompanying drawings, which are incorporated in and constitute a part of the specification, illustrate embodiments of the present disclosure.

FIG. 1 is a schematic configuration diagram of a vertical process furnace of a substrate processing apparatus suitably used in embodiments of the present disclosure, in which a portion of the process furnace is illustrated in a vertical cross-sectional view.

FIG. 2 is a schematic configuration diagram of the vertical process furnace of the substrate processing apparatus suitably used in embodiments of the present disclosure, in which a portion of the process furnace is illustrated in a cross-sectional view taken along line A-A in FIG. 1.

FIG. 3 is a schematic configuration diagram of a controller of the substrate processing apparatus suitably used in embodiments of the present disclosure, in which a control system of the controller is illustrated in a block diagram.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components are not described in detail so as not to obscure aspects of the various embodiments.

### Embodiments of the Present Disclosure

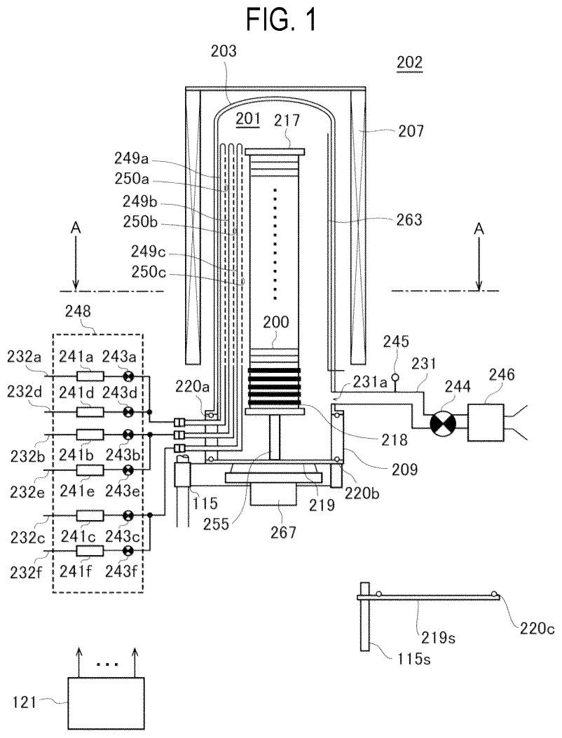

Hereinafter, embodiments of the present disclosure are described mainly with reference to FIGS. 1 to 3. The drawings used in the following description are schematic, and the dimensional relationship between respective elements, the proportions of respective elements, and the like illustrated in the drawings may not correspond to those in reality. Moreover, the dimensional relationship between respective elements, the proportions of respective elements, and the like may not match among a plurality of drawings.

### (1) Configuration of Substrate Processing Apparatus

As shown in FIG. 1, a process furnace 202 includes a heater 207 as a temperature regulator (heating part). The heater 207 is formed in a cylindrical shape and is vertically installed by being supported by a holding plate. The heater 207 functions as an activator (exciter) that activates (excites) a gas with heat.

Inside the heater 207, a reaction tube 203 is disposed concentrically with the heater 207. The reaction tube 203 is made of a heat-resistant material such as, for example, quartz (SiO₂) or silicon carbide (SiC) and is formed in a cylindrical shape with an upper end thereof closed and a lower end thereof opened. Below the reaction tube 203, a manifold 209 is disposed concentrically with the reaction tube 203. The manifold 209 is made of a metallic material such as stainless steel (SUS) or the like and is formed in a cylindrical shape with upper and lower ends thereof opened.

The upper end of the manifold 209 is engaged with the lower end of the reaction tube 203 and is configured to support the reaction tube 203. An O-ring 220a as a seal is provided between the manifold 209 and the reaction tube 203. The reaction tube 203 is installed vertically, as is the heater 207. A process container (reaction container) mainly includes the reaction tube 203 and the manifold 209. A process chamber 201 is formed in a hollow portion of the process container. The process chamber 201 is configured to be capable of accommodating wafers 200 as substrates. The wafers 200 are processed in the process chamber 201.

Nozzles 249a to 249c as first to third suppliers are installed in the process chamber 201 so as to penetrate a side wall of the manifold 209. The nozzles 249a to 249c are also referred to as first to third nozzles, respectively. The nozzles 249a to 249c are made of, for example, a heat-resistant material such as quartz, SiC, or the like. Gas supply pipes 232a to 232c are connected to the nozzles 249a to 249c, respectively. The nozzles 249a to 249c are different nozzles, and the nozzles 249a and 249c are provided adjacent to the nozzle 249b.

The gas supply pipes 232a to 232c are installed, respectively, with mass flow controllers (MFCs) 241a to 241c, which serve as flow rate controllers (flow-rate control parts), and valves 243a to 243c, which serve as on-off valves, sequentially from an upstream of a gas flow. A gas supply pipe 232d is connected to the gas supply pipe 232a on a downstream of the valve 243a. A gas supply pipe 232e is connected to the gas supply pipe 232b on a downstream of the valve 243b. A gas supply pipe 232f is connected to the gas supply pipe 232c on a downstream of the valve 243c. The gas supply pipes 232d to 232f are installed, respectively, with MFCs 241d to 241f and valves 243d to 243f, sequentially from an upstream side of a gas flow. The gas supply pipes 232a to 232f are made of, for example, a metallic material such as stainless steel or the like.

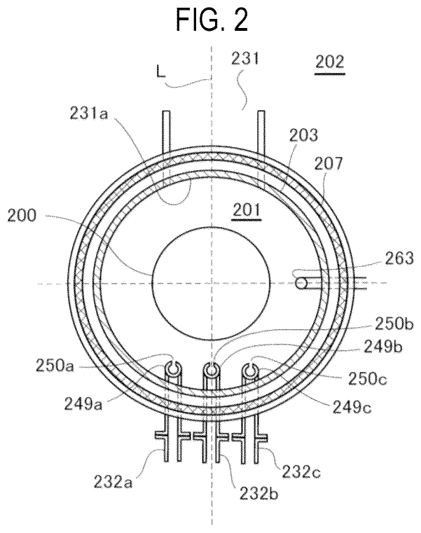

As shown in FIG. 2, the nozzles 249a to 249c are installed, respectively, in a space with an annular shape in a plane view between an inner wall of the reaction tube 203 and the wafers 200, and are installed to extend upward in an arrangement direction of the wafers 200 from a lower portion to an upper portion of the inner wall of the reaction tube 203. In other words, the nozzles 249a to 249c are respectively installed in a region horizontally surrounding a wafer arrangement region, in which the wafers 200 are arranged, at a side of the wafer arrangement region so as to be aligned along the wafer arrangement region. In a plane view, the nozzle 249b is disposed so as to face an exhaust port 231a, to be described below, on a straight line across centers of the wafers 200 loaded in the process chamber 201. The nozzles 249a and 249c are disposed so as to sandwich a straight line L passing through the nozzle 249b and a center of the exhaust port 231a from both sides along the inner wall of the reaction tube 203 (the outer peripheral portions of the wafers 200). The straight line L is also a straight line passing through the nozzle 249b and the centers of the wafers 200. That is, it may be said that the nozzle 249c is installed on a side opposite to the nozzle 249a with the straight line L interposed therebetween. The nozzles 249a and 249c are disposed line-symmetrically with the straight line L as an axis of symmetry. Gas supply holes 250a to 250c for supplying gases are formed on side surfaces of the nozzles 249a to 249c, respectively. The gas supply holes 250a to 250c are respectively opened so as to face the exhaust port 231a in a plane view and thus are able to supply gases toward the wafers 200. The gas supply holes 250a to 250c are formed in plural from a lower portion to an upper portion of the reaction tube 203.

A first precursor is supplied from the gas supply pipe 232a into the process chamber 201 through the MFC 241a, the valve 243a, and the nozzle 249a.

An addition agent is supplied from the gas supply pipe 232b into the process chamber 201 through the MFC 241b, the valve 243b, and the nozzle 249b.

A reactant is supplied from the gas supply pipe 232c into the process chamber 201 through the MFC 241c, the valve 243c, and the nozzle 249c.

An inert gas is supplied from the gas supply pipes 232d to 232f into the process chamber 201 through the MFCs 241d to 241f, the valves 243d to 243f, the gas supply pipes 232a to 232c, and the nozzles 249a to 249c, respectively. The inert gas acts as a purge gas, a carrier gas, a dilution gas, and the like.

A first precursor supply system mainly includes the gas supply pipe 232a, the MFC 241a, and the valve 243a. An addition agent supply system mainly includes the gas supply pipe 232b, the MFC 241b, and the valve 243b. A reactant supply system mainly includes the gas supply pipe 232c, the MFC 241c, and the valve 243c. An inert gas supply system mainly includes the gas supply pipes 232d to 232f, the MFCs 241d to 241f, and the valves 243d to 243f.

Any of or the entire supply systems described above may be configured as an integrated supply system 248 in which the valves 243a to 243f, the MFCs 241a to 241f and the like are integrated. The integrated supply system 248 is connected to each of the gas supply pipes 232a to 232f, and is configured such that the operations of supplying various substances (various gases) into the gas supply pipes 232a to 232f, i.e., the opening/closing operations of the valves 243a to 243f, the flow rate regulation operations by the MFCs 241a to 241f, and the like are controlled by a controller 121, which is described later. The integrated supply system 248 is configured as an integral or divided integrated unit, and is configured such that the integrated supply system 248 is capable of being attached and detached to and from the gas supply pipes 232a to 232f, and the like, on an integrated unit basis, and thus the maintenance, replacement, expansion, and the like of the integrated supply system 248 is possible to be performed on the integrated unit basis.

The exhaust port 231a for exhausting an atmosphere in the process chamber 201 is provided at a lower side of a side wall of the reaction tube 203. As shown in FIG. 2, the exhaust port 231a is installed at a position facing the nozzles 249a to 249c (gas supply holes 250a to 250c) with the wafers 200 interposed therebetween in a plane view. The exhaust port 231a may be installed along a lower portion to an upper portion of the side wall of the reaction tube 203, i.e., along the wafer arrangement region. An exhaust pipe 231 is connected to the exhaust port 231a. A vacuum pump 246 as a vacuum exhauster is connected to the exhaust pipe 231 via a pressure sensor 245 as a pressure detector (pressure detection part) for detecting a pressure inside the process chamber 201 and an APC (Auto Pressure Controller) valve 244 as a pressure regulator (pressure regulation part). The APC valve 244 is configured to be capable of performing or stopping vacuum-exhaust of an interior of the process chamber 201 by opening and closing the valve while the vacuum pump 246 is operating. Furthermore, the APC valve 244 is configured to be capable of regulating the pressure inside the process chamber 201 by adjusting a valve opening degree based on pressure information detected by the pressure sensor 245 while the vacuum pump 246 is operating. An exhaust system mainly includes the exhaust pipe 231, the APC valve 244 and the pressure sensor 245. The vacuum pump 246 may also be included in the exhaust system.

A seal cap 219 as a furnace opening lid capable of airtightly closing an opening at a lower end of the manifold 209 is installed below the manifold 209. The seal cap 219 is made of a metallic material such as, for example, stainless steel or the like, and is formed in a disc shape. On an upper surface of the seal cap 219, an O-ring 220b is installed as a seal which abuts against the lower end of the manifold 209. A rotator 267 for rotating a boat 217, to be described later, is installed below the seal cap 219. A rotating shaft 255 of the rotator 267 passes through the seal cap 219 and is connected to the boat 217. The rotator 267 is configured to rotate the wafers 200 by rotating the boat 217. The seal cap 219 is configured to be raised and lowered in a vertical direction by a boat elevator 115, which serves as a lift installed outside the reaction tube 203. The boat elevator 115 is configured as a transfer apparatus (transfer mechanism) that loads and unloads (transfers) the wafers 200 into and out of the process chamber 201 by raising and lowering the seal cap 219.

Below the manifold 209, a shutter 219s is installed as a furnace opening lid capable of airtightly closing the opening at the lower end of the manifold 209 in a state in which the seal cap 219 is lowered and the boat 217 is unloaded from the process chamber 201. The shutter 219s is made of a metallic material such as stainless steel or the like and is formed in a disk shape. An O-ring 220c as a seal that abuts against the lower end of the manifold 209 is installed on an upper surface of the shutter 219s. The opening/closing operations (the elevating operation, the rotating operation, and the like) of the shutter 219s are controlled by a shutter opening/closing mechanism 115s.

A boat 217 as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of a heat-resistant material such as, for example, quartz or SiC. Heat insulating plates 218 made of a heat-resistant material such as, for example, quartz or SiC, are supported in multiple stages at a lower portion of the boat 217.

Inside the reaction tube 203, a temperature sensor 263 as a temperature detector is installed. By regulating a state of supply of electric power to the heater 207 based on temperature information detected by the temperature sensor 263, a temperature inside the process chamber 201 becomes a desired temperature distribution. The temperature sensor 263 is installed along the inner wall of the reaction tube 203.

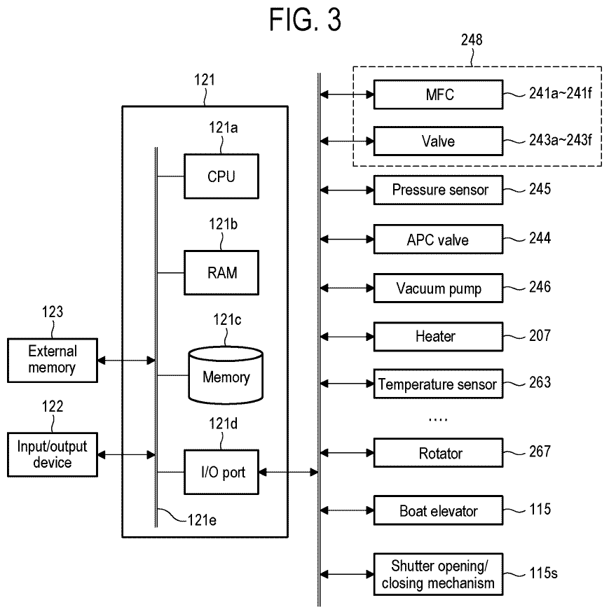

As shown in FIG. 3, the controller 121 as a control part (control means) is configured as a computer including a CPU (Central Processing Unit) 121a, a RAM (Random Access Memory) 121b, a memory 121c and an I/O port 121d. The RAM 121b, the memory 121c and the I/O port 121d are configured to be capable of exchanging data with the CPU 121a via an internal bus 121e. An input/output device 122 formed of, for example, a touch panel or the like is connected to the controller 121. In addition, an external memory 123 may be connected to the controller 121.

The memory 121c is formed of, for example, a flash memory, a HDD (Hard Disk Drive), a SSD (Solid State Drive), or the like. The memory 121c stores, in a readable manner, a control program for controlling the operation of the substrate processing apparatus, a process recipe in which procedures, conditions, and the like of substrate processing to be described later are written, and the like. The process recipe is a combination that causes the controller 121 to execute respective procedures in a below-described substrate processing in the substrate processing apparatus so as to obtain a predetermined result. The process recipe functions as a program. Hereinafter, the process recipe, the control program and the like are collectively and simply referred to as “program.” Further, the process recipe is also simply referred to as “recipe.” When the term “program” is used herein, it may mean a case of solely including the recipe, a case of solely including the control program, or a case of including both the recipe and the control program. The RAM 121b is configured as a memory area (work area) in which programs, data and the like read by the CPU 121a are temporarily held.

The I/O port 121d is connected to the MFCs 241a to 241f, the valves 243a to 243f, the pressure sensor 245, the APC valve 244, the vacuum pump 246, the temperature sensor 263, the heater 207, the rotator 267, the boat elevator 115, the shutter opening/closing mechanism 115s, and the like.

The CPU 121a is configured to be capable of reading and executing the control program from the memory 121c and reading the recipe from the memory 121c in response to an input of an operation command and the like from the input/output device 122. The CPU 121a is configured to be capable of, according to contents of the recipe thus read, controlling the flow rate regulating operations for various substances (various gases) by the MFCs 241a to 241f, the opening/closing operations of the valves 243a to 243f, the opening/closing operation of the APC valve 244, the pressure regulating operation by the APC valve 244 based on the pressure sensor 245, the start and stop of the vacuum pump 246, the temperature regulating operation of the heater 207 based on the temperature sensor 263, the rotation and the rotation speed adjusting operation of the boat 217 by the rotator 267, the raising and lowering operation of the boat 217 by the boat elevator 115, the opening/closing operation of the shutter 219s by the shutter opening/closing mechanism 115s, and the like.

The controller 121 may be configured by installing, on the computer, the above-described program recorded and stored in the external memory 123. The external memory 123 includes, for example, a magnetic disk such as a HDD or the like, an optical disk such as a CD or the like, a magneto-optical disk such as a MO or the like, a semiconductor memory such as a USB memory, a SSD, or the like, and so forth. The memory 121c and the external memory 123 are configured as computer readable recording media. Hereinafter, the memory 121c and the external memory 123 are collectively and simply referred to as “recording medium.” As used herein, the term “recording medium” may include a case of solely including the memory 121c, a case of solely including the external memory 123, or a case of including both. In addition, the provision of the program to the computer may be performed by using a communication means such as the Internet or a dedicated line without using the external memory 123.

### (2) Substrate Processing Process

An example of a method of processing a substrate, i.e., a processing sequence for forming a film on a wafer 200 as a substrate, is described as a process (method) of manufacturing a semiconductor device. In the following description, the operation of each component constituting the substrate processing apparatus is controlled by the controller 121.

In the substrate processing system sequence according to the present embodiments, a film is formed on the wafer 200 by performing a cycle a predetermined number of times (n times where n is an integer of 1 or 2 or more), the cycle including:
(a) step A of forming a first layer by supplying a first precursor and an addition agent to the wafer 200, producing a second precursor that is chemically more stable than the first precursor, and exposing and adsorbing the first precursor and the second precursor to a surface of the wafer 200; and
(b) step B of modifying the first layer into a second layer by supplying a reactant to the wafer 200.

In the present disclosure, the substrate processing sequence described above may also be denoted as follows for the sake of convenience. The same notation is also used in the following description of modifications.

(first precursor+addition agent→reactant)×n

The term “wafer” used herein may refer to a wafer itself or a stacked body including the wafer and a predetermined layer or a film formed on a surface of the wafer. The phrase “a surface of a wafer” used herein may refer to the surface of the wafer itself or a surface of a predetermined layer or the like formed on the wafer. The expression “a predetermined layer is formed on a wafer” used herein may mean that the predetermined layer is directly formed on the surface of the wafer itself or that the predetermined layer is formed on a layer or the like formed on the wafer. The term “substrate” used herein may be synonymous with the term “wafer.”

As used herein, the term “agent” includes at least one selected from the group of gaseous substances and liquid substances. Liquid substances include mist-like substances. That is, each of the addition agent, the oxidizing agent and the nitriding agent may include a gaseous substance, a liquid substance such as a mist-like substance, or both.

As used herein, the term “layer” includes at least one selected from the group of a continuous layer and a discontinuous layer. For example, each of the first layer and the second layer may include a continuous layer, a discontinuous layer, or both of them.

### (Wafer Charging and Boat Loading)

After a plurality of wafers 200 are charged to the boat 217 (wafer charging), the shutter 219s is moved by the shutter opening/closing mechanism 115s to open the opening at the lower end of the manifold 209 (shutter-open). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b. Thus, the wafer 200 is prepared in the process chamber 201.

The wafers 200 loaded into the boat 217 includes three-dimensional surfaces, i.e., surfaces that are not flat, for example, surfaces with recesses or steps formed thereon due to trenches, holes, or both.

### (Pressure Regulation and Temperature Regulation)

After the boat loading is completed, the interior of the process chamber 201, i.e., the space where the wafer 200 exists, is vacuum-exhausted (decompression-exhausted) by the vacuum pump 246 so that the pressure inside the process chamber 201 becomes a desired pressure (degree of vacuum). At this time, the pressure inside the process chamber 201 is measured by the pressure sensor 245, and the APC valve 244 is subjected to feedback control based on the measured pressure information. Further, the wafer 200 in the process chamber 201 is heated by the heater 207 to reach a desired processing temperature. At this time, the state of supply of electric power to the heater 207 is feedback-controlled based on the temperature information detected by the temperature sensor 263 so that the interior of the process chamber 201 achieves a desired temperature distribution. Moreover, the rotation of the wafer 200 by the rotator 267 is started. The vacuum-exhaust of the process chamber 201 and the heating and rotation of the wafer 200 are continuously performed at least until the processing on the wafer 200 is completed.

### (Step A)

Then, a first precursor and an addition agent are supplied to the wafer 200.

Specifically, the valves 243a and 243b are opened to allow the first precursor and the addition agent to flow into the gas supply pipes 232a and 232b, respectively. Flow rates of the first precursor and the addition agent are regulated by the MFCs 241a and 241b, respectively. The first precursor and the addition agent are supplied into the process chamber 201 via the nozzles 249a and 249b, mixed in the process chamber 201, and exhausted from the exhaust port 231a. At this time, the first precursor and the addition agent are supplied to the wafer 200 from the side of the wafer 200 (supply of first precursor+addition agent). At this time, the valves 243d to 243f may be opened to supply an inert gas into the process chamber 201 via the nozzles 249a to 249c, respectively.

Processing conditions when supplying the first precursor and the addition agent in step A are exemplified as follows.
Processing temperature: 350 to 800 degrees C., specifically 350 to 650 degrees C.
Processing pressure: 1 to 1,333 Pa, specifically 1 to 931 Pa
First precursor supply flow rate: 0.01 to 5 slm, specifically 0.1 to 2 slm
Addition agent supply flow rate: 0.01 to 10 slm, specifically 0.1 to 5 slm
Inert gas supply flow rate (per gas supply pipe): 0 to 10 slm
Each substance supply time: 1 to 120 seconds, specifically 1 to 60 seconds

In the present disclosure, the expression of a numerical range such as “350 to 800 degrees C.” means that a lower limit and an upper limit are included in the range. Therefore, for example, “350 to 800 degrees C.” means “350 degrees C. or more and 800 degrees C. or less.” The same applies to other numerical ranges. Further, the processing temperature in the present disclosure means a temperature of the wafer 200 or the temperature inside the process chamber 201, and the processing pressure means the pressure inside the process chamber 201. Moreover, the processing time means time during which the processing is continued. In addition, when 0 slm is included in the supply flow rate, 0 slm means a case where the substance (gas) is not supplied. These also hold true in the following description.

By supplying the first precursor and the addition agent to the wafer 200 under the above-mentioned processing conditions, it is possible to produce a second precursor that is more chemically stable than the first precursor, and to expose the first precursor and the second precursor to the surface of the wafer 200. The first precursor and the second precursor exposed to the surface of the wafer 200 are adsorbed to the surface of the wafer 200 to form a first layer on the surface of the wafer 200.

The second precursor produced in this step is chemically more stable than the first precursor, and therefore may be said to be a compound that is less likely to decompose than the first precursor and undergo a gas phase reaction (also called a Chemical Vapor Deposition, i.e., CVD reaction). Therefore, when the first precursor and the second precursor are exposed to the surface of the wafer 200, a proportion of the precursor (the first precursor or the second precursor) that is not decomposed (undecomposed) and does not undergo a gas phase reaction contributes to the formation of the first layer is higher than when the first precursor is solely exposed to the surface of the wafer 200 under the same processing conditions. Since the precursor (the first precursor or the second precursor) in the undecomposed state without gas phase reaction is easy to be supplied to each location in the recess of the wafer 200, a first layer with a small difference between a thickness thereof at a bottom of the recess and a thickness thereof at a top of the recess is formed. Since such a first layer is formed in step A, it is possible to improve a step coverage of the film formed on the surface of the wafer 200 by performing the cycle including steps A and B a predetermined number of times. Hereinafter, “improving the step coverage of the film formed on the surface of the wafer 200” is also simply referred to as “improving the step coverage.”

In this step, it is preferable to react a portion of the first precursor with the addition agent to modify a first bond contained in a portion of the first precursor to a second bond with a higher bond energy than the first bond, thereby changing a portion of the first precursor to the second precursor. In this way, it is possible to produce the second precursor that is more chemically stable than the first precursor from the first precursor, which makes it possible to sufficiently achieve the effect of improving the step coverage.

It is also preferable that when producing the second precursor, a bond with a lowest bond energy contained in the second precursor is higher in bond energy than a bond with a lowest bond energy contained in the first precursor. As a result, it is possible to make the chemical stability of the second precursor higher than that of the first precursor, thereby sufficiently achieving the effect of improving the step coverage.

In addition, in this step, it is also preferable to decompose a portion of the first precursor to produce an intermediate, and to react the intermediate with the addition agent to produce the second precursor that is more chemically stable than the first precursor or than both the intermediate and the first precursor. In this case, a portion of the first precursor may be modified to the second precursor by changing the first bond contained in a portion of the first precursor to the second bond with a higher bond energy than the first bond. Furthermore, a bond with a lowest bond energy contained in the second precursor may be higher in bond energy than a bond with a lowest bond energy contained in the first precursor. In this way, in step A, by producing the second precursor that is more chemically stable than the first precursor or than both the first precursor and the intermediate produced by decomposing the first precursor, it is possible to sufficiently achieve the effect of improving the step coverage.

In addition, in this step, it is preferable that an activation energy for reaction of the produced second precursor with the second layer described later is equal to or greater than an activation energy for reaction of the first precursor with the second layer, and further that the activation energy for the reaction of the first precursor with the second layer is greater than an activation energy for reaction of the intermediate, produced by decomposing the first precursor, with the second layer. As a result, reactivity of the second precursor with the second layer may be made equal to or less than reactivity of the first precursor with the second layer, and the reactivity of the first precursor with the second layer may be made lower than reactivity of the intermediate, produced by decomposing the first precursor, with the second layer. Thus, adsorption of the produced second precursor to the second layer may be made equal to or less than adsorption of the first precursor to the second layer, and the adsorption of the first precursor to the second layer may be made lower than adsorption of the intermediate, produced by decomposing the first precursor, to the second layer. Therefore, compared to the case where the first precursor is solely used, it is possible to suppress a decomposed first precursor from being multiple-adsorbed to the top of the recess of the wafer 200. As a result, it is possible to sufficiently achieve the effect of improving the step coverage. In addition, the precursors (the first precursor and the second precursor) are more easily supplied to various places of the wafer 200. For example, the precursors more easily reach the bottom of the recess of the wafer 200. This also makes it possible to sufficiently achieve the effect of improving the step coverage.

In this step, the first layer is formed by exposing the first precursor and the second precursor produced from a portion of the first precursor to the surface of the wafer 200 and adsorbing them to the surface of the wafer 200. At this time, in this step, it is preferable that a sum of an exposure amount of the first precursor and an exposure amount of the second precursor to the surface of the wafer 200 is equal to or greater than an exposure amount of the decomposed first precursor to the surface of the wafer 200, and it is more preferable that the sum of the exposure amount of the first precursor and the exposure amount of the second precursor to the surface of the wafer 200 is greater than the exposure amount of the decomposed first precursor to the surface of the wafer 200. By setting the exposure amounts of the first precursor and the second precursor to the surface of the wafer 200 in this manner, it is possible to significantly achieve the effect of improving the step coverage. In the present disclosure, when the term “first precursor”, “second precursor” or the like is simply used as a term representing a substance, it means that the substance is in an undecomposed state. On the other hand, when the term “decomposed first precursor” or the like is used as a term representing a substance, it means that the substance is in a decomposed state. Therefore, the “decomposed first precursor” includes the intermediate produced by decomposing the first precursor.

In this step, it is preferable that a sum of an adsorption amount of the first precursor and an adsorption amount of the second precursor on the surface of the wafer 200 is equal to or greater than an adsorption amount of the decomposed first precursor on the surface of the wafer 200, and it is more preferable that the sum of the adsorption amount of the first precursor and the adsorption amount of the second precursor on the surface of the wafer 200 is greater than the adsorption amount of the decomposed first precursor on the surface of the wafer 200. By setting the adsorption amounts of the first precursor and the second precursor on the wafer 200 in this way, it is possible to significantly achieve the effect of improving the step coverage.

In this step, a ratio of the sum of the adsorption amount of the first precursor and the adsorption amount of the second precursor to a sum of the adsorption amount of the first precursor, the adsorption amount of the second precursor and the adsorption amount of the decomposed first precursor on the surface of the wafer 200 is specifically set to be 50% or more, more specifically 60% or more, and even more specifically 70% or more. In addition, the ratio of the sum of the adsorption amount of the first precursor and the adsorption amount of the second precursor to the sum of the adsorption amount of the first precursor, the adsorption amount of the second precursor and the adsorption amount of the decomposed first precursor on the surface of the wafer 200 is specifically set to be 95% or less, more specifically 90% or less, and even more specifically 80% or less.

In this step, if the ratio of the sum of the adsorption amount of the first precursor and the adsorption amount of the second precursor to the sum of the adsorption amount of the first precursor, the adsorption amount of the second precursor and the adsorption amount of the decomposed first precursor on the surface of the wafer 200 is set to be less than 50%, an amount of decomposition of the first precursor may become excessive, and the step coverage may deteriorate. By setting this ratio to 50% or more, it is possible to suppress the decomposition of the first precursor, thereby reducing the amount of decomposition of the first precursor and improving the step coverage. By setting this ratio to 60% or more, it is possible to further suppress the decomposition of the first precursor, thereby further reducing the amount of decomposition of the first precursor and further improving the step coverage. By setting this ratio to 70% or more, it is possible to even further suppress the decomposition of the first precursor, thereby even further reducing the amount of decomposition of the first precursor and even further improving the step coverage. In view of this, in step A, the ratio of the sum of the adsorption amount of the first precursor and the adsorption amount of the second precursor to the sum of the adsorption amount of the first precursor, the adsorption amount of the second precursor and the adsorption amount of the decomposed first precursor on the surface of the wafer 200 is set to be specifically 50% or more, more specifically 60% or more, and even more specifically 70% or more.

In addition, in this step, if the ratio of the sum of the adsorption amount of the first precursor and the adsorption amount of the second precursor to the sum of the adsorption amount of the first precursor, the adsorption amount of the second precursor and the adsorption amount of the decomposed first precursor on the surface of the wafer 200 is set to be more than 95%, a film formation rate may decrease and productivity may deteriorate. By setting this ratio to 95% or less, it is possible to suppress the decrease in the film formation rate, and improve the productivity. By setting this ratio to 90% or less, it is possible to further suppress the decrease in the film formation rate, and further improve the productivity. By setting this ratio to 80% or less, it is possible to even further suppress the decrease in the film formation rate, and even further improve the productivity. In view of this, in step A, the ratio of the sum of the adsorption amount of the first precursor and the adsorption amount of the second precursor to the sum of the adsorption amount of the first precursor, the adsorption amount of the second precursor and the adsorption amount of the decomposed first precursor on the surface of the wafer 200 is set to be specifically 95% or less, more specifically 90% or less, and even more specifically 80% or less.

In this step, the exposure amount (adsorption amount) of the second precursor on the surface of the wafer 200 may be set to be equal to or greater than a sum of the exposure amount (adsorption amount) of the first precursor and the exposure amount (adsorption amount) of the decomposed first precursor on the surface of the wafer 200, or the exposure amount (adsorption amount) of the second precursor on the surface of the wafer 200 may be set to be greater than the sum of the exposure amount (adsorption amount) of the first precursor and the exposure amount (adsorption amount) of the decomposed first precursor on the surface of the wafer 200.

Furthermore, in this step, the exposure amount (adsorption amount) of the first precursor on the surface of the wafer 200 may be set to be equal to or greater than a sum of the exposure amount (adsorption amount) of the second precursor and the exposure amount (adsorption amount) of the decomposed first precursor on the surface of the wafer 200, or the exposure amount of the first precursor on the surface of the wafer 200 may be set to be greater than the sum of the exposure amount (adsorption amount) of the second precursor and the exposure amount (adsorption amount) of the decomposed first precursor on the surface of the wafer 200. By setting the exposure amounts of the first precursor and the second precursor on the surface of the surface of the wafer 200 in this manner, it is possible to significantly achieve the effect of improving the step coverage as described above.

After the first layer is formed on the surface of the wafer 200, the valves 243a and 243b are closed to stop the supply of the first precursor and the addition agent into the process chamber 201. Then, the process chamber 201 is vacuum-exhausted to remove gaseous substances and the like remaining in the process chamber 201 from the process chamber 201. At this time, the valves 243d to 243f are opened to supply an inert gas into the process chamber 201 through the nozzles 249a to 249c. The inert gas supplied from the nozzles 249a to 249c acts as a purge gas, and the process chamber 201 is purged (purging).
Processing conditions when purging in step A are exemplified as follows.
Processing pressure: 1 to 30 Pa
Processing time: 1 to 120 seconds, specifically 1 to 60 seconds
Inert gas supply flow rate (per gas supply pipe): 0.5 to 20 slm

The processing temperature during the purging in this step is preferably the same as the processing temperature during the supply of the first precursor and the addition agent.

### —First Precursor—

As the first precursor, for example, a compound containing a main element (main component) constituting a film formed on the wafer 200 and a halogen may be used. As the compound containing the main element constituting the film and the halogen, for example, a halosilane containing silicon (Si) and halogen may be used. Herein, the halosilane means a silane with a halogen element as a substituent. Examples of the halogen element contained in the halosilane include chlorine (Cl), fluorine (F), bromine (Br), and iodine (I). Cl, Br, and I are preferable, and Cl is more preferable. That is, among halosilanes, it is more preferable to use a chlorosilane. As the first precursor, a halosilane containing one Si in a molecule may be used, or a halosilane containing two or more (preferably two) Si in a molecule may be used. As the first precursor, it is preferable to use a halosilane containing at least one selected from the group of a Si—Si bond and a Si-hydrogen (H) bond in a molecule.

As the first precursor, for example, a chlorosilane-based gas with a Si—H bond, such as a monochlorosilane (SiH₃Cl) gas, a dichlorosilane (SiH₂Cl₂) gas, a trichlorosilane (SiHCl₃) gas or the like, or a chlorosilane-based gas with a Si—Si bond, such as a hexachlorodisilane (Si₂Cl₆) gas or the like, may be used. In addition, as the first precursor, for example, a bromosilane-based gas with a Si—H bond, such as a monobromosilane (SiH₃Br) gas, a dibromosilane (SiH₂Br₂) gas, a tribromosilane (SiHBr₃) gas or the like, or an iodosilane-based gas with a Si—H bond, such as a monoiodosilane (SiH₃I) gas, a diiodosilane (SiH₂I₂) gas, a triiodosilane (SiHI₃) gas or the like, may be used. As the first precursor, one or more of these gases may be used.

As the first precursor, for example, an alkylhalosilane containing Si, a halogen, and an alkyl group may be used. As the alkylhalosilane gas, for example, an alkylchlorosilane-based gas with a Si—Si bond, such as a 1,1,2,2-tetrachloro-1,2-dimethyldisilane ((CH₃)₂Si₂Cl₄) gas, a 1,2-dichloro-1,1,2,2-tetramethyldisilane ((CH₃)₄Si₂Cl₂) gas or the like, may be used. As the first precursor, for example, an alkylchlorosilane-based gas with a Si—H bond, such as a dimethylchlorosilane ((CH₃)₂SiHCl) or the like, may be used. As the first precursor, one or more of these gases may be used.

As the first precursor, for example, a compound containing a main element constituting a film formed on the wafer 200 and an amino group may be used. As the compound containing the main element constituting the film and the amino group, for example, an aminosilane containing Si and an amino group may be used. The aminosilane means a silane with an amino group as a substituent. The amino group contained in the aminosilane may be either an unsubstituted amino group or a substituted amino group. As the substituted amino group, for example, a substituted amino group substituted with an alkyl group with 1 to 4 carbon atoms or a substituted amino group substituted with SiH₃ may be used. The two substituents of the substituted amino group may be the same or different.

The aminosilane may preferably further contain at least one selected from the group of a Si—H bond in which Si is bonded to H, and a Si—O bond in which Si is bonded to oxygen (O), in addition to a Si—N bond in which Si is bonded to nitrogen (N) constituting an amino group. The aminosilane may also preferably contain a Si—N bond, at least one selected from the group of a Si—H bond and a Si—O bond, and a Si—C bond in which Si is bonded to carbon (C).

As the aminosilane, for example, an aminosilane-based gas with three Si—H bonds in a molecule, such as a diisopropylaminosilane (SiH₃[N(C₃H₇)₂]) gas, a di-secondary butylaminosilane (SiH₃[H(C₄H₉)₂]) gas or the like, may be used. Also, as the aminosilane, for example, an aminosilane-based gas with two Si—H bonds in a molecule, such as a bis(diethylamino)silane (SiH₂[N(C₂H₅)₂]₂) gas, a bis(dipropylamino)silane (SiH₂[N(C₃H₇)₂]₂) gas or the like, may be used. Further, as the aminosilane, for example, an aminosilane-based gas with one Si—H bond in a molecule, such as a tris(dimethylamino)silane (SiH[N(CH₃)₂]₃) or the like, may be used. As the first precursor, one or more of these gases may be used.

As the first precursor, for example, a compound containing a main element constituting a film formed on the wafer 200 and an alkoxy group may be used. As the compound containing the main element constituting the film and the alkoxy group, for example, an alkoxysilane containing Si and an alkoxy group may be used. The alkoxysilane means a silane with an alkoxy group as a substituent. The alkoxysilane possesses a property of being chemically stable and thermally stable. By using this compound, it is possible to further improve the step coverage. As the alkoxy group, for example, an alkoxy group with 1 to 4 carbon atoms may be used. The alkoxysilane is preferably an alkoxyaminosilane further containing an amino group as a substituent. That is, the alkoxysilane is preferably an alkoxyaminosilane containing a Si—N bond in which Si and N constituting the amino group are bonded, in addition to a Si—O bond in which Si and O constituting the alkoxy group are bonded.

The alkoxyaminosilane is a compound that is able to achieve both adsorptivity to the wafer 200 and chemical and thermal stability. Use of this compound may further improve the step coverage. The number of alkoxy groups in a molecule is preferably equal to or greater than the number of amino groups, and more preferably greater than the number of amino groups. The number of chemical bonds between Si and alkoxy groups (i.e., the number of Si—O bonds) is preferably equal to or greater than the number of chemical bonds between Si and amino groups (i.e., the number of Si—N bonds), and more preferably greater than the number of chemical bonds between Si and amino groups.

As the alkoxyaminosilane, for example, an alkoxyaminosilane-based gas with three Si—O bonds in a molecule, such as a (dimethylamino)trimethoxysilane (Si(OCH₃)₃[N(CH₃)₂]) gas or the like, may be used. As the alkoxyaminosilane, for example, an alkoxyaminosilane-based gas with two Si—O bonds in a molecule, such as a bis(dimethylamino)dimethoxysilane (Si(OCH₃)₂[N(CH₃)₂]₂) gas or the like, may be used. As the alkoxyaminosilane, for example, an alkoxyaminosilane-based gas with one Si—O bond in a molecule, such as a tris(dimethylamino)methoxysilane (Si(OCH₃)[N(CH₃)₂]₃) gas or the like, may be used. As the first precursor, one or more of these gases may be used.

The first precursor may be, for example, a silylamine. As the silylamine, for example, a silylamine-based gas with three Si—N bonds in a molecule, such as a trisilylamine (N(SiH₃)₃) gas or the like, may be used.

### —Addition Agent—

As the addition agent, for example, halogen, hydrogen halide, hydrocarbon, halogenated hydrocarbon, halogenated carbon, hydrogen (H₂), hydrogen nitride, or alcohol may be used.

As the halogen, for example, fluorine (F₂), chlorine (Cl₂), and bromine (Br₂) may be used. As the hydrogen halide, for example, hydrogen fluoride (HF), hydrogen chloride (HCl), hydrogen bromide (HBr), and hydrogen iodide (HI) may be used. As the hydrocarbon, for example, saturated hydrocarbon such as methane (CH₄), ethane (C₂H₆), propane (C₃H₈), butane (C₄H₁₀) or the like, and unsaturated hydrocarbon such as ethylene (C₂H₄), propylene (C₃H₆), butene (C₄H₈) or the like may be used. As the halogenated hydrocarbon, for example, trifluoromethane (CHF₃), difluoromethane (CH₂F₂), fluoromethane (CH₃F), trichloromethane (CHCl₃), dichloromethane (CH₂Cl₂), and chloromethane (CH₃Cl) may be used. As the halogenated carbon, for example, carbon tetrafluoride (CF₄) and carbon tetrachloride (CCl₄) may be used. As the hydrogen nitride, for example, ammonia (NH₃) may be used. As the alcohol, for example, methanol (CH₃OH), ethanol (C₂H₅OH), and propanol (C₃H—OH) may be used. As the addition agent, one or more of these substances may be used.

### —Inert Gas—

As the inert gas, for example, a nitrogen (N₂) gas, and a rare gas such as an argon (Ar) gas, a helium (He) gas, a neon (Ne) gas, a xenon (Xe) gas or the like may be used. One or more of these gases may be used as the inert gas. This also applies to step B described later.

### —Reaction Process for Producing Second Precursor—

Hereinafter, an example of a reaction process for producing a second precursor that is chemically more stable than the first precursor by supplying the first precursor and the addition agent to the wafer 200 in this step is described using schemes (1) to (4). In the following example, a case in which a compound containing Si as a main element constituting a film is used as the first precursor is described by way of example.

### Schemes (1) and (2)

By using a specific first precursor and a specific addition agent under the above-mentioned processing conditions (particularly, the processing temperature), it is possible to allow a reaction between the first precursor and the addition agent to occur, for example, as illustrated in the following scheme (1), and produce a second precursor that is more chemically stable than the first precursor. In addition, by using a specific first precursor and a specific addition agent under the above-mentioned processing conditions (particularly, the processing temperature), it is possible to allow a reaction between the addition agent and an intermediate produced by decomposing a portion of the first precursor to occur, for example, as illustrated in the following scheme (2), and produce a second precursor that is more chemically stable than the first precursor or each of the intermediate and the first precursor. In this step, the reaction shown in the scheme (1) and the reaction shown in the scheme (2) may occur simultaneously.

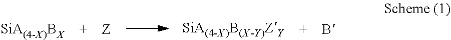

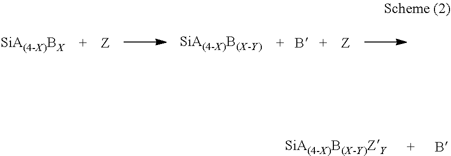

In the scheme (1), “SiA_{(4-X)}B_{X}” represents the first precursor, “Z” represents the addition agent, “SiA_{(4-X)}B_{(X-Y)}Z′_{Y}” represents the second precursor, X represents an integer of 1 to 3, and Y represents an integer satisfying 1≤Y≤X. In the scheme (2), “SiA_{(4-X)}B_{X}” represents the first precursor, “Z” represents the addition agent, “SiA_{(4-X)}B_{(X-Y)}” represents the intermediate, “SiA_{(4-X)}B_{(X-Y)}Z′_{Y}” represents the second precursor, X represents an integer of 1 to 3, and Y represents an integer satisfying 1≤Y≤X.

Each of the schemes (1) and (2) is divided into a first aspect using a first precursor which is a compound (e.g., halosilane, or alkylhalosilane) containing Si and a halogen, and a second aspect using a first precursor which is a compound (e.g., aminosilane, alkoxyaminosilane, or silylamine) containing Si and an amino group. The second aspect is further divided into an aspect (2-1 aspect) using a first precursor which is a compound containing Si and an amino group and containing a Si—H bond, and an aspect (2-2 aspect) using a first precursor which is a compound containing Si and an amino group and not containing a Si—H bond.

### First Aspect

First, the first aspect is described. In the case of the first aspect, in the schemes (1) and (2), A represents a halogen atom or an alkyl group, B represents a hydrogen atom (H), Z represents a halogen, a hydrogen halide, a hydrocarbon, a halogenated hydrocarbon, or a halogenated carbon, Z′ represents a group containing a portion of molecules of Z, and B′ represents a product produced by breaking an Si—B bond, or a product produced by bonding a portion of molecules of B to a portion of the molecules of Z. However, at least one A represents a halogen atom. Also, when X is 1 or 2 and the first precursor and the second precursor contain multiple As, the multiple As may be different from each other or may be the same. When Y is 2 or 3 and the second precursor contains multiple Z's, the multiple Z's may be different from each other or may be the same.

The first precursor used in the first aspect contains a Si—H bond as a Si—B bond. The Si—H bond is lower in bond energy than other chemical bonds (e.g., Si-halogen bond, etc.). In other words, it may be said that the Si—H bond exhibits a property of being more easily broken than other chemical bonds (e.g., Si-halogen bond, etc.) under the above-mentioned processing conditions.

In the case of the scheme (1), under the above-mentioned processing conditions, the first precursor reacts with the addition agent Z, and the Si—H bond portion with a lower bond energy reacts with the addition agent Z to produce a second precursor containing a Si—Z′ bond in which a portion of the molecules of the addition agent Z is bonded to Si.

In the case of the scheme (2), under the above-mentioned processing conditions, H is broken from the Si—H bond of the first precursor, thereby producing an intermediate “SiA_{(4-X)}B_{(X-Y)}” containing Si with Y dangling bonds. The produced intermediate is an unstable substance in which the Si—H bond portion of the first precursor is radicalized. Therefore, the dangling bond of the intermediate is bonded to a portion of the molecules of the addition agent Z, producing a second precursor containing a Si—Z′ bond.

The Si—Z′ bond (e.g., Si—N bond, Si-halogen bond, Si—C bond, etc.) in the second precursor produced as described above is higher in bond energy than the Si—H bond in the first precursor. Thus, in the first aspect, a portion of the first precursor is reacted with the addition agent to modify the first bond (herein, Si—H bond) contained in a portion of the first precursor into the second bond (herein, Si—N bond, Si-halogen bond, Si—C bond, or the like as the Si—Z′ bond) with a higher bond energy than the first bond, thereby changing a portion of the first precursor into the second precursor. This makes it possible to produce the second precursor that is more chemically stable than the first precursor.

The Si—H bonds in the first precursor may be partially or entirely modified to Si—Z′ bonds. In other words, the second precursor may contain Si—H bonds (the Si—H bonds may remain) or may not contain Si—H bonds.

In the case of the first aspect, among the above-mentioned processing conditions, the processing temperature is specifically set to 400 to 800 degrees C. By selecting such a processing temperature, the reactions shown in the above-mentioned schemes (1) and (2) may be carried out more efficiently.

### 2-1 Aspect

Next, the 2-1 aspect is described. In the case of the 2-1 aspect, in the schemes (1) and (2), A represents an amino group, an alkyl group, or an alkoxy group, B represents a hydrogen atom, Z represents hydrogen, hydrogen nitride, alcohol, hydrocarbon, halogenated hydrocarbon, or halogenated carbon, Z′ represents a group containing a portion of the molecules of Z, and B′ represents a product produced by breaking the Si—B bond, or a product produced by bonding a portion of the molecules of B to a portion of the molecules of Z. However, at least one A represents an amino group. The amino group represented by A may be either an unsubstituted amino group or a substituted amino group. The substituted amino group is particularly preferred. As the substituted amino group, for example, a substituted amino group substituted with an alkyl group with 1 to 4 carbon atoms or a substituted amino group substituted with SiH₃ may be used. In addition, when X is 1 or 2 and the first precursor and the second precursor contain multiple As, the multiple As may be different from each other or may be the same. When Y is 2 or 3 and the second precursor contains multiple Z's, the multiple Z's may be different from each other or may be the same.

The first precursor used in the 2-1 aspect contains a Si—H bond as a Si—B bond. The Si—H bond is lower in bond energy than other chemical bonds (e.g., Si—N bond, Si—O bond, etc.). In other words, it may be said that the Si—H bond exhibits a property of being more easily broken than other chemical bonds (e.g., Si—N bond, Si—O bond, etc.) under the above-mentioned processing conditions.

In the case of the scheme (1), under the above-mentioned processing conditions, the Si—H bond portion of the first precursor with a lower bond energy reacts with the addition agent Z to produce a second precursor containing a Si—Z′ bond in which a portion of the molecules of the addition agent Z is bonded to Si.

In the case of the scheme (2), under the above-mentioned processing conditions, H is broken from the Si—H bond of the first precursor, and an intermediate “SiA_{(4-X)}B_{(X-Y)}” containing Si with Y dangling bonds is produced. The produced intermediate is an unstable substance in which the Si—H bond portion of the first precursor is radicalized. The unstable intermediate quickly reacts with the addition agent Z, and a portion of the molecules of the addition agent Z is bonded to the dangling bond portion, producing a second precursor containing a Si—Z′ bond.

The Si—Z′ bond (e.g., Si—N bond, Si-halogen bond, Si—C bond, etc.) in the second precursor produced as described above is higher in bond energy than the Si—H bond in the first precursor. In this way, in the 2-1 aspect as well, a portion of the first precursor is modified into the second precursor by allowing a portion of the first precursor to react with the addition agent to modify the first bond (herein, Si—H bond) contained in a portion of the first precursor into the second bond (herein, Si—N bond, Si-halogen bond, Si—C bond, or the like as the Si—Z′ bond) with a higher bond energy than the first bond. As a result, in the 2-1 aspect, it is possible to produce the second precursor that is more chemically stable than the first precursor.

Further, in the 2-1 aspect as well, the Si—H bonds in the first precursor may be partially or entirely modified to Si—Z′ bonds. In other words, the second precursor may contain Si—H bonds (the Si—H bonds may remain) or may not contain Si—H bonds.

In addition, in the first precursor used in the 2-1 aspect, A may be a substituted amino group substituted with an alkyl group (e.g., a dimethylamino group, a diethylamino group, a dipropylamino group, etc.). In this case, depending on the processing conditions and the addition agents, A, which is a substituted amino group substituted with an alkyl group, may react with the addition agent Z (e.g., NH₃) and may be modified to an unsubstituted amino group (—NH₂). That is, in this case, A, which is a substituted amino group substituted with an alkyl group in the first precursor, becomes an unsubstituted amino group (—NH₂) in the second precursor. The N—H bond of the unsubstituted amino group is higher in bond energy than the N—C bond of the amino group substituted with an alkyl group. Therefore, when the above-mentioned modification occurs in A, it is possible to produce the second precursor that is chemically more stable than the first precursor, compared to when this modification does not occur.

In the case of the 2-1 aspect, among the above-mentioned processing conditions, the processing temperature is specifically set to 400 to 700 degrees C. By selecting such a processing temperature, the reactions shown in the above-mentioned schemes (1) and (2) may be carried out more efficiently.

### 2-2 Aspect

Next, the 2-2 aspect is described. In the case of the 2-2 aspect, in the schemes (1) and (2), A represents an alkyl group or an alkoxy group, B represents an amino group, Z represents hydrogen nitride, alcohol, hydrocarbon, halogenated hydrocarbon, or halogenated carbon, Z′ represents a group containing a portion of the molecules of Z, and B′ represents a product produced by breaking the Si—B bond, or a product produced by bonding a portion of the molecules of B to a portion of the molecules of Z. However, at least one B is a substituted amino group substituted with an alkyl group (e.g., a dimethylamino group, a diethylamino group, a dipropylamino group, etc.). When the second precursor contains multiple Z's, the multiple Z's may be different from each other or may be the same.

The first precursor used in the 2-2 aspect contains a substituted amino group substituted with an alkyl group at B. The N—C bond of the substituted amino group substituted with an alkyl group is lower in bond energy than other chemical bonds (e.g., Si—O bond, Si—C bond, O—C bond, C—H bond, etc.).

In the case of the scheme (1), under the above-mentioned processing conditions, B containing an N—C bond with a lower bond energy in the first precursor reacts with the addition agent Z to produce a second precursor containing Z′ containing a bond (e.g., an N—H bond, etc.) with a higher bond energy than the N—C bond.

In the case of the scheme (2), under the above-mentioned processing conditions, B containing an N—C bond in the first precursor is broken to produce an intermediate “SiA_{(4-X)}B_{(X-Y)}” containing Si with Y dangling bonds. The produced intermediate is an unstable substance in which the Si—B bond portion of the first precursor is radicalized. The unstable intermediate quickly reacts with the addition agent Z, and a portion of the molecules of the addition agent Z is bonded to the dangling bond portion of Si, producing a second precursor containing a Si—Z′ bond.

The bond (e.g., N—H bond, etc.) contained in Z′ in the second precursor produced as described above is higher in bond energy than the bond (e.g., N—C bond, etc.) contained in B in the first precursor. In this way, in the 2-2 aspect as well, a portion of the first precursor is reacted with the addition agent to modify the first bond (herein, N—C bond) contained in a portion of the first precursor into the second bond (herein, N—H bond, etc.) with a higher bond energy than the first bond, thereby modifying a portion of the first precursor into the second precursor. As a result, in the 2-2 aspect, it is possible to produce the second precursor that is more chemically stable than the first precursor.

In the case of the 2-2 aspect, among the above-mentioned processing conditions, the processing temperature is specifically set to 450 to 800 degrees C. By selecting such a processing temperature, the reactions shown in the above-mentioned schemes (1) and (2) may be carried out more efficiently.

### Schemes (3) and (4)

Furthermore, by using a specific first precursor and a specific addition agent under the above-mentioned processing conditions (particularly, the processing temperature), it is possible to allow a reaction between the first precursor and the addition agent to occur, for example, as illustrated in the following scheme (3), and produce a second precursor that is more chemically stable than the first precursor. In addition, by using a specific first precursor and a specific addition agent under the above-mentioned processing conditions (particularly, the processing temperature), it is possible to allow a reaction between the addition agent and an intermediate produced by decomposing a portion of the first precursor to occur, for example, as illustrated in the following scheme (4), and produce a second precursor that is more chemically stable than the first precursor or each of the intermediate and the first precursor. In this step, the reaction shown in the scheme (3) and the reaction shown in the scheme (4) may occur simultaneously.

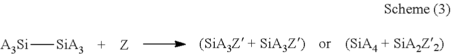

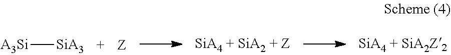

In the scheme (3), “A₃Si—SiA₃” represents the first precursor, “Z” represents the addition agent, and “(SiA₃Z′+SiA₃Z′)” or “(SiA₄+SiA₂Z′₂)” represents the second precursor. In the scheme (4), “A₃Si—SiA₃” represents the first precursor, “Z” represents the addition agent, “SiA₂” represents the intermediate, and “SiA₄” and “SiA₄+SiA₂Z′₂” represent the second precursor.

In the schemes (3) and (4), A represents a halogen atom or an alkyl group, Z represents a halogen, a hydrogen halide, a hydrocarbon, a halogenated hydrocarbon, or a halogenated carbon, and Z′ represents a group containing a portion of the molecules of Z. When the second precursor contains multiple Z's, the multiple Z's may be different from each other or may be the same.

The Si—Si bond in the first precursor represented by “A₃Si—SiA₃” is lower in bond energy than the Si-A bond (e.g., a Si-halogen bond, or a Si—C bond).

In the case of the scheme (3), under the above-mentioned processing conditions, the first precursor reacts with the addition agent Z to produce two molecules of “SiA₃Z′” or two molecules of “SiA₄” and “SiA₂Z′₂” as the second precursor.

In the case of the scheme (4), under the above-mentioned processing conditions, the Si—Si bond of the first precursor is broken, and one molecule of an intermediate “SiA₂” containing Si with two dangling bonds is produced. At this time, a second precursor represented by “SiA₄” is also produced. The produced intermediate is an unstable substance in which the Si—Si bond portion of the first precursor is radicalized. The unstable intermediate quickly reacts with the addition agent Z, and a portion of the molecules of the addition agent Z is bonded to the dangling bond portion of Si, producing “SiA₂Z′₂” as the second precursor.

The Si—Z′ bond (e.g., Si-halogen bond, Si—H bond, Si—C bond, etc.) in the second precursor produced as described above is higher in bond energy than the Si—Si bond in the first precursor. In this manner, a portion of the first precursor is modified into the second precursor by allowing a portion of the first precursor to react with the addition agent to modify the first bond (herein, Si—Si bond) contained in a portion of the first precursor into the second bond (herein, Si-halogen bond, Si—H bond, Si—C bond, etc.) with a higher bond energy than the first bond. As a result, in this example, it is possible to produce the second precursor that is more chemically stable than the first precursor.

In the case of the reactions shown in the schemes (3) and (4), among the above-mentioned processing conditions, the processing temperature is specifically set to 350 to 800 degrees C. By selecting such a processing temperature, the reactions shown in the schemes (3) and (4) may be carried out more efficiently.

### [Step B]

After step A is completed, a reactant is supplied to the wafer 200, i.e., the wafer 200 after the first layer is formed.

Specifically, the valve 243c is opened to allow the reactant to flow into the gas supply pipe 232c. A flow rate of the reactant is regulated by the MFC 241c. The reactant is supplied into the process chamber 201 via the nozzle 249c, mixed in the process chamber 201, and exhausted from the exhaust port 231a. At this time, the reactant is supplied to the wafer 200 from the side of the wafer 200 (reactant supply). At this time, the valves 243d to 243f may be opened to supply an inert gas into the process chamber 201 through the nozzles 249a to 249c, respectively. Processing conditions when supplying the reactant in step B are exemplified as follows.
Processing temperature: 350 to 800 degrees C., specifically 350 to 650 degrees C.
Processing pressure: 1 to 4,000 Pa, specifically 1 to 931 Pa
Reactant supply flow rate: 1 to 20 slm, specifically 1 to 10 slm
Inert gas supply flow rate (per gas supply pipe): 0 to 10 slm
Each substance supply time: 1 to 120 seconds, specifically 1 to 60 seconds

By supplying the reactant to the wafer 200 under the above-mentioned processing conditions, it is possible to modify the first layer into the second layer. Specifically, in this step, by supplying the reactant to the wafer 200 under the above-mentioned processing conditions, it is possible to add elements contained in the reactant to the first layer and thus modify a composition of the first layer. This makes it possible to modify (convert) the first layer into the second layer with a composition different from that of the first layer.

After the first layer is modified (converted) into the second layer, the valve 243c is closed to stop the supply of the reactant into the process chamber 201. Then, the gaseous substances and the like remaining in the process chamber 201 are removed (purged) from the process chamber 201 by the same processing procedure and processing conditions as those for purging in step A (purging). A processing temperature for purging in this step is preferably the same as the processing temperature for supplying the reactant.

### —Reactant—

As the reactant, for example, an oxidizing agent may be used. As the oxidizing agent, for example, an O-containing gas, or a H- and O-containing gas may be used. As the O-containing gas, for example, an oxygen (O₂) gas, an ozone (O₃) gas, or the like may be used. As the H- and O-containing gas, for example, a water vapor (H₂O gas), a hydrogen peroxide (H₂O₂) gas, a H₂ gas+O₂ gas, a H₂ gas+O₃ gas, or the like may be used. That is, as the H- and O-containing gas, a H-containing gas+O-containing gas (reducing gas+oxidizing gas) may also be used. In this case, a deuterium (D₂) gas may also be used instead of the H₂ gas as the H-containing gas, i.e., the reducing gas. As the reactant, one or more of these gases may be used.

The description of two gases together, such as “H₂ gas+O₂ gas” in the present disclosure means a mixed gas of H₂ gas and O₂ gas. When supplying the mixed gas, the two gases may be mixed (premixed) in a supply pipe and then supplied into the process chamber 201, or the two gases may be separately supplied into the process chamber from different supply pipes and then mixed (post-mixed) within the process chamber 201.

As the reactant, for example, a nitriding agent may also be used. As the nitriding agent, a N- and H-containing gas may be used. As the N- and H-containing gas, for example, a hydrogen nitride-based gas such as an ammonia (NH₃) gas, a diazene (N₂H₂) gas, a hydrazine (N₂H₄) gas, a N₃H₈ gas, or the like may be used. Furthermore, as the N- and H-containing gas, for example, a C-, N- and H-containing gas may be used. As the C-, N- and H-containing gas, for example, an ethylamine-based gas such as a monoethylamine (C₂H₅NH₂) gas, a diethylamine ((C₂H₅)₂NH) gas, a triethylamine ((C₂H₅)₃N) gas or the like, a methylamine-based gas such as a monomethylamine (CH₃NH₂) gas, a dimethylamine ((CH₃)₂NH) gas, a trimethylamine ((CH₃)₃N) gas or the like; and an organic hydrazine-based gas such as a monomethylhydrazine ((CH₃)HN₂H₂) gas, a dimethylhydrazine ((CH₃)₂N₂H₂) gas, a trimethylhydrazine ((CH₃)₂N₂(CH₃)H) gas or the like may be used. One or more of these gases may be used as the reactant.

As the reactant, for example, a C- and H-containing gas, or a boron (B)-containing gas may be used. As the C- and H-containing gas, for example, a hydrocarbon-based gas such as an ethylene (C₂H₄) gas, an acetylene (C₂H₂) gas, a propylene (C₃H₆) gas or the like may be used. As the B-containing gas, for example, a trichloroborane (BCl₃) gas, a diborane (B₂H₆) gas, a triethylborane ((C₂H₅)₃B) gas or the like may be used. As the reactant, one or more of these gases may be used.

### [Performing a Predetermined Number of Times]

By performing a cycle a predetermined number of times (n times where n is an integer of 1 or 2 or more), the cycle including performing the above-mentioned steps A and B asynchronously, i.e., alternately without synchronization, it is possible to form (grow) a film with a desired thickness on the surface of the wafer 200. It is preferable to repeat the above-mentioned cycle multiple times. In other words, it is preferred that a thickness of the second layer formed per cycle is set to be smaller than the desired thickness, and the above-mentioned cycle is repeated multiple times until a thickness of the film formed by stacking the second layers reaches the desired thickness.

By using the above-mentioned various first precursors, various addition agents, and various reactants, a Si-containing film such as a silicon oxide film (SiO film), a silicon nitride film (SiN film), a silicon oxycarbonitride film (SiOCN film), a silicon oxycarbide film (SiOC film), a silicon oxynitride film (SiON film), a silicon carbonitride film (SiCN film), a silicon carbide film (SiC film), a silicon borocarbonitride film (SiBCN film), a silicon boronitride film (SiBN film), a silicon borocarbide film (SiBC film), a silicon borocarbonitride film (SiBOCN film), a silicon borooxynitride film (SiBON film), a silicon borooxycarbide film (SiBOC film) may be formed on the surface of the wafer 200.

### (After-Purge and Atmospheric Pressure Restoration)

After the formation of the film on the wafer 200 is completed, an inert gas as a purge gas is supplied into the process chamber 201 from each of the nozzles 249a to 249c and is exhausted from the exhaust port 231a. As a result, the interior of the process chamber 201 is purged, and any gases, reaction by-products, and the like remaining in the process chamber 201 are removed from the interior of the process chamber 201 (after-purge). Thereafter, the atmosphere in the process chamber 201 is replaced with the inert gas (inert gas replacement), and the pressure inside the process chamber 201 is restored to normal pressure (atmospheric pressure restoration).

### (Boat Unloading and Wafer Discharging)

Thereafter, the seal cap 219 is lowered by the boat elevator 115, and the lower end of the manifold 209 is opened. Then, the processed wafers 200 are unloaded from the lower end of the manifold 209 to an outside of the reaction tube 203 while being supported by the boat 217 (boat unloading). After the boat is unloaded, the shutter 219s is moved and the opening at the lower end of the manifold 209 is sealed by the shutter 219s via the O-ring 220c (shutter closing). The processed wafers 200 are discharged from the boat 217 after they are unloaded to the outside of the reaction tube 203 (wafer discharging).

### (3) Effects of the Present Embodiments

According to the present embodiments, one or more of the following effects may be obtained.

In step A, the second precursor, which is more chemically stable than the first precursor, is produced, and the first precursor and the second precursor are exposed to and adsorbed on the surface of the wafer 200 to form the first layer. Since the second precursor is more chemically stable than the first precursor, the proportion of which the precursors (the first precursor and the second precursor) not decomposed (undecomposed) and not undergoing a gas phase reaction contributes to the formation of the first layer is higher than when the first precursor is solely used. The precursors (the first precursor and the second precursor) not decomposed (undecomposed) and not undergoing a gas phase reaction are supplied to each locations in the recess of the wafer 200, and thus the first layer is formed with a small difference between the thickness thereof at the bottom of the recess and the thickness thereof at the top of the recess. As a result of the formation of such a first layer, it is possible to improve the step coverage of the film formed on the wafer 200 (the film formed by stacking the second layers obtained by modifying the first layer).

In step A, it is preferable to adopt a combination in which the first precursor includes a compound containing a main element constituting a film and a halogen, and the addition agent includes at least one selected from the group of a halogen, a hydrogen halide, a hydrocarbon, a halogenated hydrocarbon, and a halogenated carbon. When the first precursor and the addition agent are used in this combination, it is possible to efficiently produce the second precursor that is more chemically stable than the first precursor. As a result, the effect of improving the step coverage of the film formed on the wafer 200 may be obtained more significantly.

In step A, it is preferable to adopt a combination in which the first precursor includes at least one selected from the group of a compound containing a main element constituting a film and an amino group, a compound containing a main element constituting the film and an alkoxy group, and a silylamine, and the addition agent includes at least one selected from the group of hydrogen, hydrogen nitride, alcohol, hydrocarbon, halogenated hydrocarbon, and halogenated carbon. When the first precursor and the addition agent are used in this combination, it is possible to efficiently produce the second precursor that is more chemically stable than the first precursor. As a result, the effect of improving the step coverage of the film formed on the wafer 200 may be obtained more significantly.

In step A, it is preferable to use a compound containing a main element constituting a film and an alkoxy group, such as an alkoxysilane or the like, as the first precursor, and it is preferable that such a compound further contains an amino group. That is, it is preferable to use a compound containing a main element constituting a film, an alkoxy group, and an amino group, such as an alkoxyaminosilane or the like, as the first precursor. When the first precursor is a compound with such a structure, the effect of improving the step coverage of the film formed on the wafer 200 may be obtained more significantly.

In particular, in the compound containing the main element constituting the film, the alkoxy group, and the amino group, which is used as the first precursor, the number of alkoxy groups in one molecule is preferably equal to or greater than the number of amino groups, and more preferably greater than the number of amino groups. Furthermore, the number of chemical bonds between atoms of the main element and the alkoxy group is preferably equal to or greater than the number of chemical bonds between the atoms of the main element and the amino group, and more preferably greater than the number of chemical bonds between the atoms of the main element and the amino group. When the first precursor is a compound with such a structure, the effect of improving the step coverage of the film formed on the wafer 200 may be obtained more significantly.

### (4) Modifications

The substrate processing sequence according to the present embodiments may be modified as shown in the following modifications. Unless otherwise specified, the processing procedure and processing conditions in each step of the modifications may be the same as the processing procedure and processing conditions in each step of the substrate processing sequence described above.

### Modification 1

As shown in the processing sequences below, step B may be a step of non-simultaneously supplying different types of reactants (e.g., a first reactant, a second reactant, and a third reactant shown below). Herein, n is an integer of 1 or more or an integer of 2 or more, and m is an integer of 1 or more or an integer of 2 or more. In addition, the first reactant, the second reactant, and the third reactant shown below are reactants with different molecular structures. As the first reactant, the second reactant, and the third reactant, any of the various reactants described above may be used.

(first precursor+addition agent→first reactant→second reactant)×n

(first precursor+addition agent→first reactant→second reactant→third reactant)×n

[(first precursor+addition agent→first reactant)×m→second reactant]×n

[(first precursor+addition agent→first reactant)×m→second reactant→third reactant]×n

[(first precursor+addition agent→first reactant→second reactant)×m→third reactant]×n

This modification also provides the same effects as those of the above-mentioned embodiments. Moreover, according to this modification, elements contained in the different types of reactants are added to the first layer, which makes it possible to modify the composition of the first layer stepwise with good controllability. This allows the first layer to be modified (converted) into a second layer with a desired composition. As a result, a film with a desired composition may be formed with good controllability. This modification also makes it possible to form the various films described above.

### Other Embodiments of the Present Disclosure

The embodiments of the present disclosure are specifically described above. However, the present disclosure is not limited to the above-described embodiments, and various changes may be made without departing from the spirit of the present disclosure.

In the above-described embodiment, the example in which a compound containing Si as the main element constituting the film is used as the first precursor is described. However, the main element constituting the film is not limited to Si. For example, in addition to Si, a semiconductor element such as germanium (Ge) or the like and a metal element such as titanium (Ti), tantalum (Ta), molybdenum (Mo), tungsten (W), ruthenium (Ru), aluminum (Al), zirconium (Zr), hafnium (Hf) or the like may be exemplified as the main element constituting the film. Even when a compound containing an element other than Si as the main element constituting the film is used as the first precursor, the same effects as those of the above-described embodiments may be obtained. In these cases, it is possible to form a film containing a semiconductor element such as Ge or the like or a film containing a metal element such as Ti, Ta, Mo, W, Ru, Al, Zr, Hf or the like, apart from the Si-containing film.

It is preferable that recipe used for each process is prepared individually according to processing contents and are recorded and stored in the memory 121c via an electric communication line or an external memory 123. When starting each process, it is preferable that the CPU 121a appropriately selects a suitable recipe from a plurality of recipes recorded and stored in the memory 121c according to the processing contents. This makes it possible to form films of various film types, composition ratios, film qualities and film thicknesses with high reproducibility in one substrate processing apparatus. In addition, the burden on an operator may be reduced, and each process may be quickly started while avoiding operation errors.

The above-described recipes are not limited to the newly prepared ones, but may be prepared by, for example, changing the existing recipes already installed in the substrate processing apparatus. In the case of changing the recipes, the recipes after the change may be installed in the substrate processing apparatus via an electric communication line or a recording medium in which the recipes are recorded. In addition, the input/output device 122 provided in the existing substrate processing apparatus may be operated to directly change the existing recipes already installed in the substrate processing apparatus.

In the above-described embodiments, the example in which a film is formed by using a batch-type substrate processing apparatus capable of processing a plurality of substrates at a time is described. The present disclosure is not limited to the above-described embodiments, but may be suitably applied to, for example, a case where a film is formed using a single-substrate type substrate processing apparatus for processing one or several substrates at a time. Furthermore, in the above-described embodiments, the example in which a film is formed using a substrate processing apparatus with a hot-wall type process furnace is described. The present disclosure is not limited to the above-described embodiments, but may also be suitably applied to a case where a film is formed using a substrate processing apparatus with a cold-wall type process furnace.

Even when these substrate processing apparatuses are used, each process may be performed under the same processing procedures and processing conditions as those of the above-described embodiments and modifications. The same effects as those of the above-described embodiments and modifications may be obtained.

The above-described embodiments and modifications may be used in combination as appropriate. The processing procedure and processing conditions at this time may be, for example, the same as the processing procedures and processing conditions of the above-described embodiments and modifications.

According to the present disclosure, it is possible to improve step coverage of a film formed on a substrate.

While certain embodiments are described, these embodiments are presented by way of example, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of processing a substrate, comprising:
forming a film on the substrate by performing a cycle a predetermined number of times, the cycle including:
(a) forming a first layer by supplying a first precursor and an addition agent to the substrate, producing a second precursor that is chemically more stable than the first precursor, and exposing and adsorbing the first precursor and the second precursor to a surface of the substrate; and
(b) modifying the first layer into a second layer by supplying a reactant to the substrate.

2. The method of claim 1, wherein in (a), a portion of the first precursor is modified into the second precursor by allowing a portion of the first precursor to react with the addition agent to modify a first bond contained in a portion of the first precursor into a second bond with a higher bond energy than the first bond.

3. The method of claim 1, wherein a bond with a lowest bond energy contained in the second precursor is higher in bond energy than a bond with a lowest bond energy contained in the first precursor.

4. The method of claim 1, wherein in (a), a portion of the first precursor is decomposed to produce an intermediate, and the intermediate is reacted with the addition agent to produce the second precursor, which is more chemically stable than the first precursor or each of the intermediate and the first precursor.

5. The method of claim 4, wherein an activation energy for reaction of the second precursor with the second layer is equal to or greater than an activation energy for reaction of the first precursor with the second layer, and the activation energy for reaction of the first precursor with the second layer is greater than an activation energy for reaction of the intermediate with the second layer.

6. The method of claim 1, wherein in (a), a sum of an exposure amount of the first precursor and an exposure amount of the second precursor on the surface of the substrate is set to be equal to or greater than an exposure amount of a decomposed first precursor on the surface of the substrate, the exposure amount of the second precursor on the surface of the substrate is set to be equal to or greater than a sum of the exposure amount of the first precursor and the exposure amount of the decomposed first precursor on the surface of the substrate, or the exposure amount of the first precursor on the surface of the substrate is set to be equal to or greater than a sum of the exposure amount of the second precursor and the exposure amount of the decomposed first precursor on the surface of the substrate.

7. The method of claim 1, wherein in (a), a sum of an adsorption amount of the first precursor and an adsorption amount of the second precursor on the surface of the substrate is set to be equal to or greater than an adsorption amount of a decomposed first precursor on the surface of the substrate, the adsorption amount of the second precursor on the surface of the substrate is set to be equal to or greater than a sum of the adsorption amount of the first precursor and the adsorption amount of the decomposed first precursor on the surface of the substrate, or the adsorption amount of the first precursor on the surface of the substrate is set to be equal to or greater than a sum of the adsorption amount of the second precursor and the adsorption amount of the decomposed first precursor on the surface of the substrate.

8. The method of claim 1, wherein in (a), a ratio of a sum of an adsorption amount of the first precursor and an adsorption amount of the second precursor on the surface of the substrate to a sum of the adsorption amount of the first precursor, the adsorption amount of the second precursor and an adsorption amount of a decomposed first precursor on the surface of the substrate is set to be 50% or more.

9. The method of claim 1, wherein in (a), a ratio of a sum of an adsorption amount of the first precursor and an adsorption amount of the second precursor on the surface of the substrate to a sum of the adsorption amount of the first precursor, the adsorption amount of the second precursor and an adsorption amount of a decomposed first precursor on the surface of the substrate is set to be 95% or less.

10. The method of claim 1, wherein the first precursor includes a compound containing a main element constituting the film and a halogen, and the addition agent includes at least one selected from the group of halogen, hydrogen halide, hydrocarbon, halogenated hydrocarbon, and halogenated carbon.

11. The method of claim 1, wherein the first precursor includes at least one selected from the group of a compound containing a main element constituting the film and an amino group, a compound containing the main element and an alkoxy group, and a silylamine, and the addition agent includes at least one selected from the group of hydrogen, hydrogen nitride, alcohol, hydrocarbon, halogenated hydrocarbon, and halogenated carbon.

12. The method of claim 1, wherein the first precursor includes a compound containing a main element constituting the film and an alkoxy group.

13. The method of claim 12, wherein the compound further contains an amino group.

14. The method of claim 13, wherein a number of alkoxy groups in a molecule of the compound is equal to or greater than a number of amino groups.

15. The method of claim 13, wherein a number of chemical bonds between atoms of the main element and the alkoxy group in the compound is equal to or greater than a number of chemical bonds between the atoms of the main element and the amino group.

16. The method of claim 12, wherein the compound is an alkoxysilane.

17. The method of claim 13, wherein the compound is an alkoxyaminosilane.

18. A method of manufacturing a semiconductor device comprising the method of claim 1.

19. A substrate processing apparatus, comprising:
a first precursor supply system configured to supply a first precursor to a substrate;
an addition agent supply system configured to supply an addition agent to the substrate;
a reactant supply system configured to supply a reactant to the substrate; and
a controller configured to be capable of controlling the first precursor supply system, the addition agent supply system, and the reactant supply system, so as to perform a process of forming a film on the substrate by performing a cycle a predetermined number of times, the cycle including:
(a) forming a first layer by supplying the first precursor and the addition agent to the substrate, producing a second precursor that is chemically more stable than the first precursor, and exposing and adsorbing the first precursor and the second precursor to a surface of the substrate; and
(b) modifying the first layer into a second layer by supplying the reactant to the substrate.

20. A non-transitory computer-readable recording medium storing a program that causes, by a computer, a substrate processing apparatus to perform:
forming a film on a substrate by performing a cycle a predetermined number of times, the cycle including:
(a) forming a first layer by supplying a first precursor and an addition agent to the substrate, producing a second precursor that is chemically more stable than the first precursor, and exposing and adsorbing the first precursor and the second precursor to a surface of the substrate; and
(b) modifying the first layer into a second layer by supplying a reactant to the substrate.
